(19) United States
(12) Patent Application Publication
(10) Pub. No.: US 2006/0017113 A1
(43) Pub. Date: Jan. 26, 2006

(54) High transconductance and drive current high voltage MOS transistors

(75) Inventors: Haifeng Xu, Gainesville, FL (US); Kenneth Kyongyop O, Gainesville, FL (US)

Correspondence Address: AKERMAN SENTERFITT, P.O. BOX 3188, WEST PALM BEACH, FL, 33402-3188, US

(73) Assignee: UNIVERSITY OF FLORIDA RESEARCH FOUNDATION, INC., GAINESVILLE, FL (US)

(21) Appl. No.: 11/186,366

(22) Filed: Jul. 21, 2005

Related U.S. Application Data
(60) Provisional application No. 60/589,949, filed on Jul. 21, 2004.

(51) Int. Cl. H01L 29/76

(52) U.S. Cl. 257/369

(57) ABSTRACT

A composite MOS transistor (100) includes a first MOS sub-transistor (105) having a first gate dielectric thickness (106), and a second MOS sub-transistor (155) in series connection with the first MOS sub-transistor having a second gate dielectric thickness (107). The second gate dielectric thickness (107) is substantially thicker than the first gate dielectric thickness (106) preferably being at least 50% thicker. Composite MOS transistors generally provide a breakdown voltage (V_{ds}) approaching that of the second MOS sub-transistor (155) and a threshold voltage, transconductance and drive current all approaching that of the first MOS sub-transistor (105), such as being within 20%, and preferably within 10%, of the reference parameter. A level shifting circuit includes first and at least a second drive transistor, wherein the drive transistors are composite MOS transistors.

### CROSS REFERENCE TO RELATED APPLICATIONS

This application claims the benefit of and incorporates by reference in its entirety U.S. Provisional Application No. 60/589,949 entitled “INCREASE OF TRANSCONDUCTANCE AND DRIVE CURRENT FOR HIGH VOLTAGE MOS TRANSISTORS BY COMBINING THIN-OXIDE TRANSISTOR WITH THICK-OXIDE TRANSISTOR”, filed on Jul. 21, 2004.

### STATEMENT REGARDING FEDERALLY SPONSORED RESEARCH OR DEVELOPMENT

Not applicable.

### TECHNICAL FIELD OF THE INVENTION

This invention relates generally to the field of semiconductor devices and, more specifically to high voltage MOS transistors, such as high voltage input/output (“I/O”) transistors.

### BACKGROUND OF THE INVENTION

Input/output (I/O) voltage disparities are often encountered by designers of networking, telecom, server and computing products. For example, level-shifting is generally required to interface two circuits operating at significantly different voltage levels, such as for bus-to-bus or processor-to-bus data transfer, where the buses or processors have differing voltages. In one application, TTL signals are level shifted to CMOS logic levels.

To provide the capability to maintain compatibility to the systems using circuits fabricated in older generations of technologies, high voltage I/O transistors became part of a standard technology offering. For instance, in 1.2-V 0.13-μm CMOS processes, 3.3-V 0.34-μm I/O transistors are available. The 1.2-V logic levels are translated to the 3.3-V logic levels using an interface circuit formed with 3.3-V transistors, such as the level shifting circuit shown in FIG. 1 [See Wen-Tai Wang, Ming-Dou Ker, Mi-Chang Chiang, and Chung-Hui Chen, “Level Shifters for High-Speed 1-V to 3.3-V Interfaces in a 0.13-μm Cu-Interconnection/Low-K CMOS Technology”, VLSI Technology, Systems, and Applications, 2001. Proceedings of Technical Papers. 2001 International Symposium on, 18-20 Apr. 2001, pp. 307-310]. A problem with this circuit is that the gates of 3.3-V drive transistors (M₃ and M₄) with higher threshold voltage (V_{T}˜0.7 V) are driven by a circuit whose output switches between 0 and 1.2 V. Because of this, the gate overdrive, thus the drive current is limited. These in turn limit the switching speed of I/O circuits. Thus, conventional MOS high voltage I/O transistors limit the speed and performance of MOS I/O circuits.

### SUMMARY

A composite MOS transistor comprises a first MOS transistor having a first gate dielectric thickness, and a second MOS transistor in series connection with the first MOS transistor having a second gate dielectric thickness. First and second transistors when components of composite transistors according to the invention are hereafter generally referred to as sub-transistors for clarity purposes. The second gate dielectric thickness is substantially thicker than the first gate dielectric thickness. As used herein, the phrase “substantially thicker” refers to a second dielectric thickness being at least 30% thicker, preferably being at least 50% thicker, such as 60%, 70%, 80%, 100%, 200% or 400% greater than the first dielectric thickness. Although generally described as being a gate oxide, composite transistors according to the invention are in now way limited to oxide dielectrics.

The series connection can comprise a diffusion common to both the first MOS sub-transistor and the second MOS sub-transistor, such as a n+ or p+ diffusion. The gate of the first sub-transistor is preferably electrically tied to a gate of the second sub-transistor. The first and second MOS sub-transistors can comprise NMOS or PMOS transistors. Composite transistors according to the invention generally provide a breakdown voltage (V_{ds}) approaching that of the second MOS transistor and a threshold voltage, transconductance and drive current all approaching that of the first MOS transistor. As used herein, the word “approaching” a given electrical parameter is defined as the parameter being within 20%, and preferably within 10%, of the reference parameter. A level shifting circuit includes first and at least a second drive transistor, wherein the drive transistors are composite MOS transistors.

### BRIEF DESCRIPTION OF THE DRAWINGS

A fuller understanding of the present invention and the features and benefits thereof will be accomplished upon review of the following detailed description together with the accompanying drawings, in which:

FIG. 1 shows the schematic of a conventional level shifter circuit. The 1.2-V and 3.3-V transistors are shown in different symbols. The 3.3-V drive transistors (M₃ and M₄) have low drive current because the gate voltage is limited to 1.2 V.

FIG. 2 shows a cross sectional view of a composite nMOS transistor according to an embodiment of the invention.

FIG. 3(a) shows a simplified schematic for the composite transistor shown in FIG. 2.

FIG. 3(b) shows an exemplary layout for the composite transistor shown in FIG. 2.

FIG. 4 shows data from transistors fabricated using the Taiwan Semiconductor Manufacturing Company Ltd. (TSMC) 0.18 μm CMOS process comparing drain current measured for a composite MOS transistor according to the invention as compared to a conventional high voltage I/O transistor and thin-oxide transistor fabricated on the same chip.

FIG. 5 shows data from transistors fabricated using the TSMC 0.18 μm CMOS process comparing transconductance for a composite MOS transistor according to the invention as compared to a conventional high voltage I/O transistor and thin-oxide transistor fabricated on the same chip.

FIG. 6 shows data from transistors fabricated using the United Microelectronics Corp. (UMC) 0.13 μm CMOS process comparing I_{DS}-V_{DS} characteristics of composite, 3.3-V thick-oxide, and 1.2-V thin-oxide transistors. The drawn channel lengths are 0.34, 0.34 and 0.12 μm, respectively. The widths are 7.4, 10.0 and 13.1 μm, respectively. The widths are chosen such a way to keep gate capacitance (C_{gg}) the same for fairer comparison. Biased at the same V_{GS}, the composite transistor has more than 2 times the drain current of 3.3-V transistor.

FIG. 7. shows data from transistors fabricated using the UMC 0.13 μm CMOS process comparing I_{DS}-V_{GS} curves for composite transistor according to the invention and 3.3-V thick-oxide transistors at V_{DS}=3.3 V and V_{DS}=005 V are shown in linear and log scales. The drawn channel lengths are 0.34 μm. The widths are 7.4 and 10.0 μm, respectively. The drive current of the composite transistor is at least 2 times of that for the 3.3-V transistor.

### DETAILED DESCRIPTION

A composite MOS transistor includes a first MOS sub-transistor having a first gate dielectric thickness, and a series connected second MOS sub-transistor having a second gate dielectric thickness. The second gate dielectric thickness is substantially thicker than the first gate dielectric thickness. Composite transistors according to the invention achieve high transconductance and drive current as compared to conventional high voltage I/O transistors. Such composite transistors can be used in CMOS processes, as well as BICMOS processes.

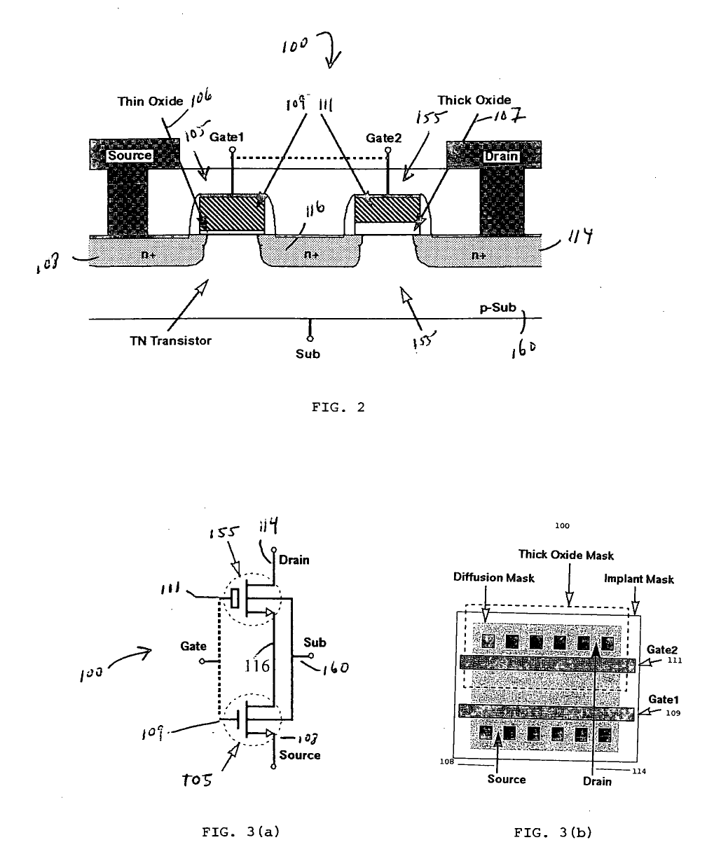

FIG. 2 shows a cross sectional view of a composite transistor 100 according to an embodiment of the invention. Composite transistor 100 includes a thin oxide nMOS sub-transistor 105 having a thin gate dielectric layer 106 and a thick oxide NMOS sub-transistor 155 having a thick gate dielectric layer 107 hooked up in series through a common n+ diffusion 116. Although shown hooked in series using n+ diffusion 116, sub-transistors 105 and 155 need not share an n+ diffusion to be connected in series, such as when respective n+ diffusions are tied by a metal or another electrically conductive layer.

The n+ diffusion 108 on the side of sub-transistor 105 acts as a source, and the n+ diffusion 114 on the side of sub-transistor 155 as acts as a drain for composite transistor 100. The gates 109 and 111 of sub-transistors 105 and 155, respectively, are shown electrically connected together to form a single common gate, such as by having their polysilicon gates connected together to form a single gate, or by using a metal connector. The gates 109 and 111 can be formed from any suitable material, such as heavily doped polysilicon.

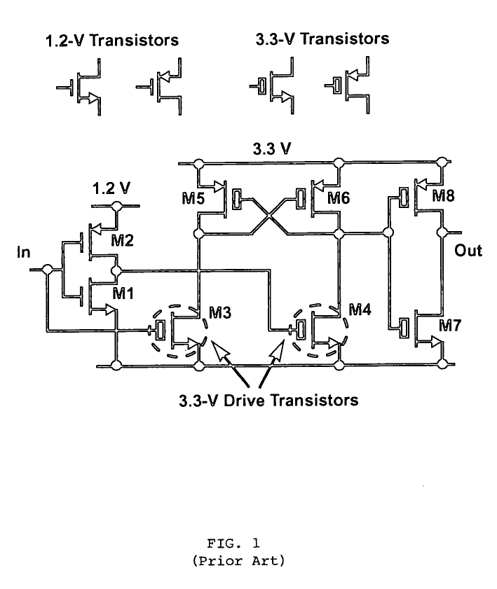

The bodies of sub-transistors 105 and 155 are connected through the common p-substrate 160. Accordingly, composite transistor 100 shown in FIG. 1 provides four terminals and thus functions and can be operated as a single nMOS transistor.

Compared to a thin oxide transistor such as transistor 105 taken alone, composite transistor 100 has lower drive current due to the addition sub-transistor 155. However, sub-transistor 155 helps composite transistor 100 to tolerate a larger voltage drop across the drain and gate, and across the drain and source as compared to an isolated thin oxide transistor. This increases the breakdown voltage of composite transistor structure compared to that for a single thin oxide transistor.

In a preferred embodiment, the channel length of sub-transistor 155 is only about ⅔ of the minimum channel length for thick oxide transistors. For example, for transistors fabricated using the UMC 0.13 μm CMOS process (See Example 2) where 1.2 V thin oxide transistors are 0.12-μm length and 3.3 V thick oxide transistors are 0.33 μm in length, composite transistor 100 can comprise a series combination of a 0.12-μm long thin-oxide sub-transistor 105 and a 0.22-μm long thick-oxide sub-transistor 155. 0.22 μm is about 65% of the minimum length of 3.3-V transistors. This channel length change increases the drive current. However, because of strong short channel effects, sub-transistor 155 generally cannot be turned off, and thus cannot work as a transistor on its own. Sub-transistor 155 can only generally be used in combination with other transistors, such as with sub-transistor 105 to form composite transistor 100.

Although embodied as an nMOS transistor 100, the composite transistor can be pMOS transistor based. Moreover, composite transistor 100 can be formed in a well, such as in a p-well diffused into an n-substrate (not shown).

A simplified schematic of composite nMOS transistor 100 is shown in FIG. 3(a). The breakdown voltage between drain 114 and source 108 is expected to be higher than a conventional thin oxide transistor, such sub-transistor 105 alone.

An exemplary layout for composite transistor 100 is shown in FIG. 3(b). Masks for diffusion, thick oxide and implant are shown. The square shaped features shown are the plurality of metal contacts provided for both source 108 and drain 114.

As demonstrated in the Examples provided below, composite transistors according to the invention provide a breakdown voltage approaching that of a conventional thick oxide transistor with the threshold voltage, transconductance and drive current approaching that of a conventional thin oxide transistor. Thus, the invention combines the advantages of both the thin oxide transistor and thick oxide transistor into one composite MOS structure, without the need for any process modification and associated extra fabrication cost.

This invention can be used in a variety of applications, including level shifter circuits. In this application, the invention can improve speed performance of the interface circuit part of digital I/O buffers. This composite transistor structure can also be used to build RF (Radio Frequency) power amplifiers, with better power handling capacity and power added efficiency.

### EXAMPLES

The present invention is further illustrated by the following specific Examples, which should not be construed as limiting the scope or content of the invention in any way.

### Example 1

### Results from Transistors Fabricated Using the TSMC 0.18 μm CMOS Process

Composite NMOS transistors according to the invention, as well as thick oxide and thin oxide transistors for comparison, were fabricated using a Taiwan Semiconductor Manufacturing Company Ltd. (TSMC) 0.18 μm CMOS process and characterized. Table 1 shows a comparison of breakdown voltage and threshold voltage obtained for a composite MOS transistor according to the invention, as compared to a high voltage I/O transistor (3.3-V MOS) and thin-oxide transistor (1.8-V MOS) fabricated on the same Si chip.

TABLE 1

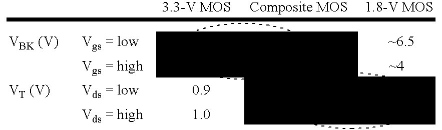

Table 1 shows the composite MOS transistor provides a comparable breakdown voltage (V_{BK}) at both high and low V_{GS} conditions. The low V_{GS} condition was V_{GS}=0 V; the high V_{GS} condition was V_{GS}=3.3V/1.8V/1.8 V for 3.3-V MOS/Composite MOS/1.8-V MOS, respectively. The breakdown characteristics of the composite transistor are primarily determined by sub-transistor 155. This is because sub-transistor 155 sustains a large portion of the drain to source voltage, and the middle diffusion voltage, or the drain voltage of sub-transistor 105 is kept below the breakdown voltage sub-transistor 105. This in turn allows the drain node of composite NMOS transistor 100 to be biased at a higher voltage such as the bias used for conventional I/O transistors.

The composite MOS transistor was also found to provide a lower threshold voltage (V_{T}) as compared to a conventional high voltage I/O transistor for both high and low V_{ds} conditions. This evidences that the formation of the n-channel in the composite transistor 100 is primarily determined by sub-transistor 105.

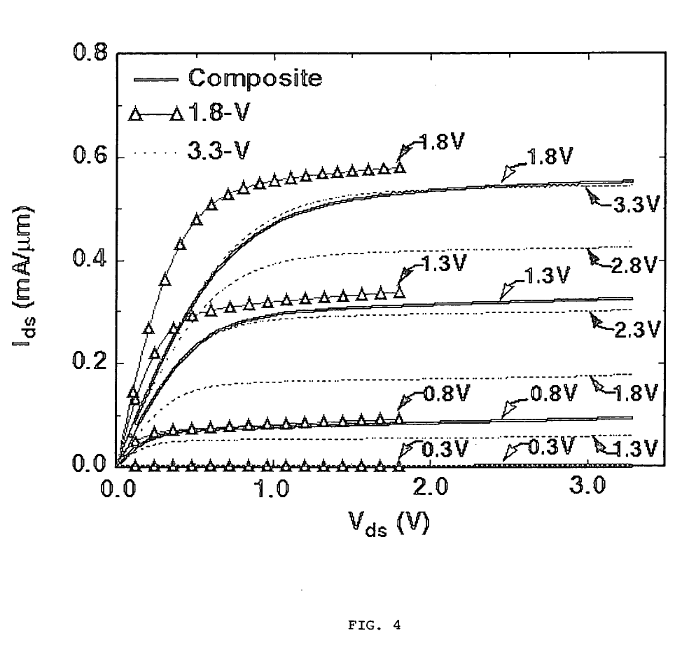

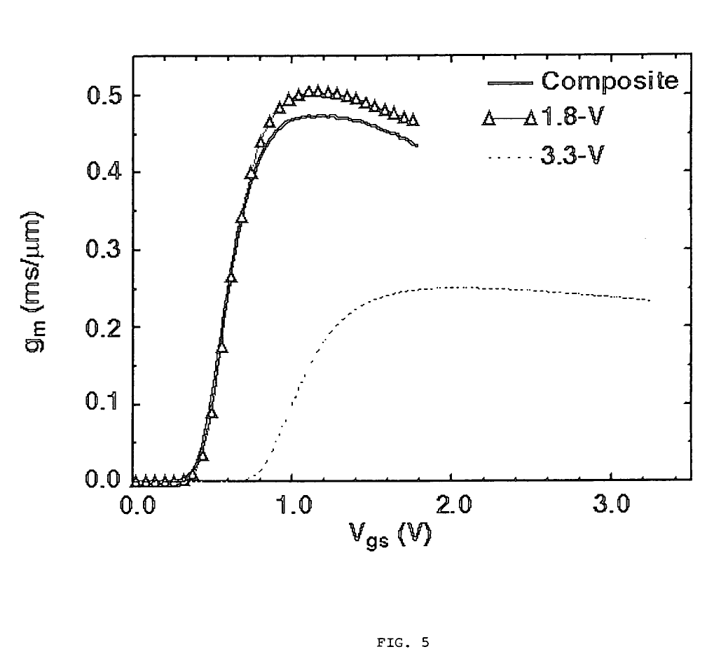

FIG. 4 shows a comparison of drain current for the same composite MOS transistor according to the invention as compared to a conventional high voltage I/O transistor and thin-oxide transistor fabricated on the same chip. For unit channel width, the composite transistor is seen to provide about 3 times the saturation current as compared with the conventional high voltage I/O transistor. FIG. 5 shows a comparison of transconductance (gₘ) for the composite MOS transistor, and conventional high voltage I/O transistor and thin-oxide transistor showing about 2 times of the peak transconductance as compared to the conventional high voltage I/O transistor.

### Example 2

### Results from Transistors Fabricated Using the UMC 0.13 μM CMOS Process

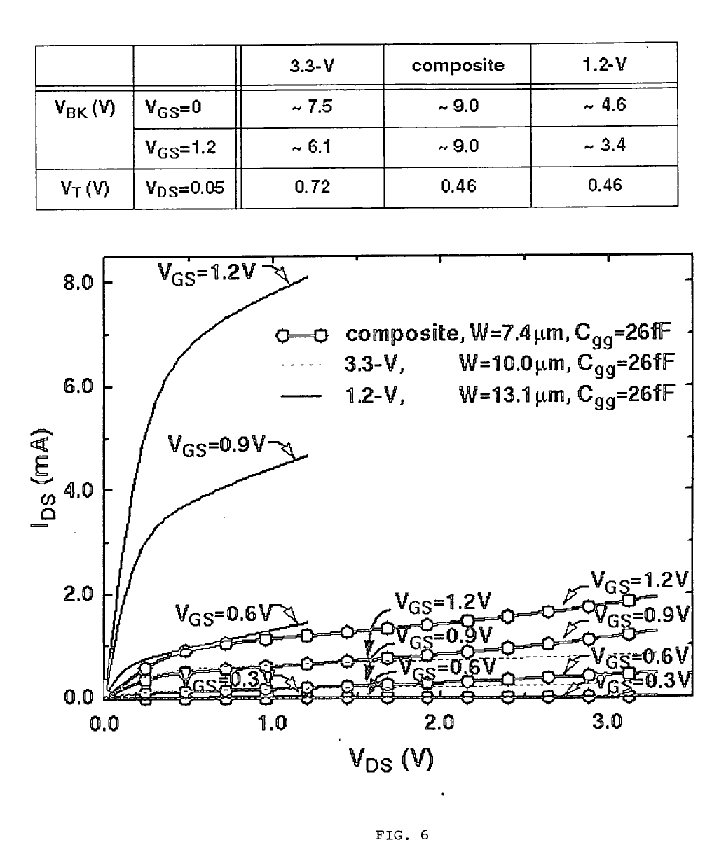

Composite NMOS transistors according to the invention, as well as thick oxide and thin oxide transistors for comparison, were fabricated using a United Microelectronics Corp. (UMC) 0.13 μm CMOS process and characterized. The DC properties of composite nMOS transistor were measured. For comparison, the characteristics of conventional thick-oxide I/O transistors (3.3-V transistor) and conventional thin-oxide transistors (1.2-V transistor) were also measured. The drawn gate lengths were 0.34 μm (composite transistor), 0.34 μm (3.3-V transistor) and 0.12 μm (1.2-V transistor), respectively. The drain-to-source breakdown voltages (V_{BK}'s) and threshold voltages (V_{T}'s) for these transistors are listed in FIG. 6. The composite NMOS transistor 100 was found to have a comparable breakdown voltage to the 3.3-V transistor, which is around 2 times that of the 1.2-V transistor. The breakdown (Vds) characteristics of composite transistor 100 is primarily determined by the thick oxide sub-transistor 155. This is because the thick oxide sub-transistor 155 sustains a large portion of the drain to source voltage, and the middle diffusion voltage, or the drain voltage of sub-transistor 105 is kept below the breakdown voltage of 1.2-V transistor. This in turn allows the drain node of composite nMOS transistor to be biased at a higher voltage, such as the voltage used for the 3.3-V I/O transistor.

While its breakdown voltage is high, the composite nMOS transistor 100 has the same low threshold voltage as that for an 1.2-V transistor, which is 0.26 V below that of a 3.3-V transistor. This is consistent with the sub-transistor 105 having a lowered threshold voltage, and the formation of the n-channel in the composite structure being primarily determined by the sub-transistor 105. If the drive transistors M3 and M4 in FIG. 1 were replaced by composite transistors 100, then the gate overdrive (V_{GS}−V_{T}=1.2-V_{T}) would be increased by about 54%. Having a thin-oxide sub-transistor 105 as part of the structure of composite transistor 100, however, generally limits the maximum gate-to-source voltage (V_{GS}) to 1.2 V.

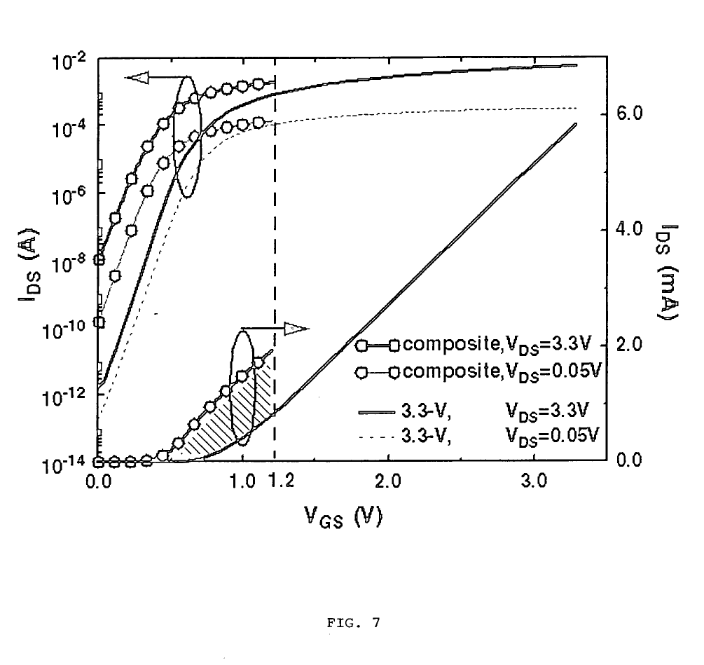

I_{DS}-V_{DS} curves of composite transistor 100, 3.3-V thick-oxide and 1.2-V thin-oxide transistors are shown in FIG. 7. When the widths are the same, because of the thin gate oxide region in a composite transistor, composite transistor 100 has more gate capacitance than a conventional 3.3-V transistor. For a fairer comparison, the currents were normalized to the same gate capacitance (C_{gg} of 26 fF). The capacitances for structures at V_{GS}=1.2 V and V_{DS}=0.0 V were extracted from the measured y₁₁. The corresponding widths for composite, 3.3-V and 1.2-V transistors are 7.4, 10.0 and 13.1 μm, respectively. Biased at the same gate-to-source voltage (V_{GS}), the composite nMOS transistor 100 fabricated using the UMC 0.13 μm CMOS Process was found to deliver more than 2 times the current of the 3.3-V transistor.

In FIG. 7, I_{DS}-V_{GS} curves of composite transistor 100 and 3.3-V transistors are also compared. Once again, the currents were normalized by keeping the gate capacitance at 26 fF. In the log scale plots, the normal subthreshold behaviors are observed at both V_{DS}=3.3 V and V_{DS}=0.05 V. At V_{DS}=3.3 V, the off-state current for composite structure is comparable to that for the 1.2-V transistor at V_{DS}=1.2 V. However, it is almost 4 decades higher than that for the 3.3-V transistor. Because the number of I/O transistors used in an integrated circuit is limited, the somewhat higher leakage should not be a problem. The linear scale plots show that once again I_{DS} of the composite nMOS transistor is at least 2 times that of the 3.3-V transistor. The improvement of I_{DS} at low V_{GS} is even more dramatic due to the lower threshold voltage of composite transistor. With its drain connected to 3.3 V and gate swept from 0 V to 1.2 V, it is clearly shown by the shaded area in FIG. 7 that the composite transistor can deliver larger current than the 3.3-V transistor. This higher current at given gate/input capacitance suggests that the 3.3-V drive transistors in the level shifter circuit (FIG. 1) can be replaced by the composite nMOS transistors to reduce the propagation delay. Accordingly, using the composite MOS transistors according to the invention, the speed performance of digital I/O circuits can be improved.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as described in the claims.

We claim:

1. A composite MOS transistor, comprising:
a first MOS sub-transistor having a first gate dielectric thickness, and
a second MOS sub-transistor in series connection with said first MOS transistor having a second gate dielectric thickness, said second gate dielectric thickness being substantially thicker than said first gate dielectric thickness.

2. The composite transistor of claim 1, wherein said series connection comprises a diffusion common to both said first MOS sub-transistor and said second MOS sub-transistor.

3. The composite transistor of claim 2, wherein said diffusion common to both said first MOS sub-transistor and said second MOS sub-transistor comprises an n+ diffusion.

4. The composite transistor of claim 1, wherein a gate of said first MOS sub-transistor is electrically tied to a gate of said second MOS sub-transistor.

5. The composite transistor of claim 1, wherein said second gate oxide thickness is between 50% and 200% thicker than said first gate oxide thickness.

6. The composite transistor of claim 1, wherein said first and said second MOS sub-transistors comprise NMOS transistors.

7. The composite transistor of claim 1, wherein said first and said second MOS sub-transistors comprise PMOS transistors.

8. The composite transistor of claim 1, wherein said composite transistor provides a breakdown voltage (V_{ds}) approaching that of said second MOS transistor and a threshold voltage, transconductance and drive current all approaching that of said first MOS transistor.

9. A level shifting circuit, comprising:
first and at least a second drive transistor, wherein said drive transistors each comprise: a composite MOS transistor, said composite transistor comprising:
a first MOS sub-transistor having a first gate dielectric thickness, and
a second MOS sub-transistor in series connection with said first MOS transistor having a second gate dielectric thickness, said second gate dielectric thickness being substantially thicker than said first gate dielectric thickness.

10. The level shifting circuit of claim 9, wherein said series connection comprises a diffusion common to both said first MOS sub-transistor and said second MOS sub-transistor.

11. The level shifting circuit of claim 9, wherein said first and said second MOS sub-transistors comprise NMOS transistors.

12. The level shifting circuit of claim 9, wherein a gate of said first MOS sub-transistor is electrically tied to a gate of said second MOS sub-transistor.
